(19) United States
(12) Patent Application Publication
(10) Pub. No.: US 2026/0047160 A1
(43) Pub. Date: Feb. 12, 2026

(54) PLANAR JFET WITH ENHANCED CHANNEL CONTROL

(71) Applicant: Microchip Technology Incorporated, Chandler, AZ (US)

(72) Inventors: Shesh Mani Pandey, Gilbert, AZ (US); Kevin Speer, Bentonville, AR (US)

(73) Assignee: Microchip Technology Incorporated, Chandler, AZ (US)

(21) Appl. No.: 19/247,609

(22) Filed: Jun. 24, 2025

Related U.S. Application Data
(60) Provisional application No. 63/682,250, filed on Aug. 12, 2024.
(60) Provisional application No. 63/704,400, filed on Oct. 7, 2024.

(51) Int. Cl. H10D 62/17; H10D 30/83

(52) U.S. Cl. CPC H10D 62/343; H10D 30/831; H10D 62/328

(57) ABSTRACT

The planar junction field-effect transistor provides enhanced channel control. A method of making such a JFET is also disclosed. A volume of semiconductor material includes a first end and a second end, a source and a first gate are located at the first end, a drain is spaced apart from the source, and a channel is provided between the source and the drain. A second gate is located between the source and drain so as to be surrounded, or buried, in a first dimension and a second dimension by the semiconductor material, and thereby divides the channel into multiple non-linear channel paths. The gates cooperatively determine the channel paths and enhance the channel control. The second gate may include an extension in a third dimension through the semiconductor material. The extension may present an exposed surface for an electrical terminal for receiving a voltage.

### RELATED APPLICATION

The present U.S. non-provisional patent application is related to and claims priority benefit of earlier-filed U.S. provisional patent application titled “Planar JFET with Enhanced Channel Control,” Ser. No. 63/704,400, filed Oct. 7, 2024, and U.S. provisional patent application titled “Planar JFET with Buried Gate,” Ser. No. 63/682,250, filed Aug. 12, 2024. The entire content of each of the identified earlier-filed applications is incorporated by reference as if fully set forth herein.

### FIELD

The present disclosure relates to junction field-effect transistors and methods of making them, and, more particularly, the various examples described herein concern a planar junction field-effect transistor with enhanced channel control, and a method of making a planar junction field-effect transistor with enhanced channel control.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a planar JFET with enhanced channel control, and a method of making a planar JFET with enhanced channel control. Broadly, a second gate component divides a channel into multiple paths for electrical current to flow between the source and the drain. Examples advantageously provide improved performance, including improved channel control and lower electrical resistance to electrical current flow through the channel.

In an example, a planar JFET with enhanced channel control may include a source, a drain spaced apart from the source, a channel extending between the source and the drain, a first gate including a left first gate component and a right first gate component, and a second gate. The second gate may include a front second gate component located between and spaced apart from the source and the drain, and include a first side and a second side. The front second gate component may divide the channel into a first non-linear channel path and a second non-linear channel path. The first non-linear channel path may extend from the source toward the drain, turn and extend along the front second gate component in a first direction, and turn around the first side of the front second gate component and extend to the drain, wherein the front second gate component and the left first gate component cooperate to control a first electrical current flowing through the first non-linear channel path. The second non-linear channel path may extend from the source toward the drain, turn and extend along the front second gate component in a second direction, and turn around the second side of the front second gate component and extend to the drain, wherein the front second gate component and the right first gate component cooperate to control a second electrical current flowing through the second non-linear channel path.

The preceding example may further include any one or more of the following features. The front second gate component may be located at least partially between the left first gate component and the drain, and the front second gate component may be located at least partially between the right first gate component and the drain. The left first gate component may extend at least partially along the first side of the front second gate component, and the right first gate component may extend at least partially along the second side of the front second gate component. The front second gate component may be spaced apart from the source by a distance that is at least sufficient to achieve a breakdown voltage between the front second gate component and the source. The front second gate component may extend between two-tenths (0.2) and two (2) micrometers in a first dimension and between two-tenths (0.2) and two (2) micrometers in a second dimension. The source may include an N+ material, the drain may include an N+ substrate material, and the first gate and the second gate may include a P+ material. The front second gate component may include an extension in a third dimension, and the second gate may include a rear second gate component extending at an angle from the extension of the front second gate component. The planar JFET may further include a first electrical terminal provided on the source, a second electrical terminal provided on the drain, a third electrical terminal provided on the left first gate component, a fourth electrical terminal provided on the right first gate component, and a fifth electrical terminal provided on the rear second gate component.

In another example, a planar JFET with enhanced channel control may include a volume of semiconductor material, a source, a drain, a channel, a first gate, and a second gate. The volume of semiconductor material may include a first end, a second end, a first side, and a second side. The source may be located at the first end of the semiconductor material, the drain may be located at the second end and spaced apart from and opposite the source, and the channel may extend between the source and the drain through the semiconductor material. The first gate may include a left first gate component located at the first end and the first side of the volume of semiconductor material and spaced apart from the source, and a right first gate component located at the first end and the second side of the volume of semiconductor material and adjacent to and spaced apart from the source. The second gate may include a front second gate component and a rear second gate component. The front second gate component may be located spaced apart from and between the source and the drain and surrounded in two dimensions by the volume of semiconductor material, and the front second gate component may be located at least partially between the left first gate component and the drain and at least partially between the right first gate component and the drain, and may include a first side and a second side and an extension in a third dimension through the volume of semiconductor material. The rear second gate component may extend from the extension of the front second gate component to a surface at the first end of the volume of semiconductor material. The front second gate component may divide the channel into a first non-linear channel path and a second non-linear channel path. The first non-linear channel path may extend from the source toward the drain, turn and extend along the front second gate component in a first direction, and turn around the first side of the front second gate component and extend to the drain, wherein the front second gate component and the left first gate component cooperate to control a first electrical current flowing through the first non-linear channel path. The second non-linear channel path may extend from the source toward the drain, turn and extend along the front second gate component in a second direction, and turn around the second side of the front second gate component and extend to the drain, wherein the front second gate component and the right first gate component cooperate to control a second electrical current flowing through the second non-linear channel path.

The preceding example may further include any one or more of the following features. The front second gate component may be spaced apart from the source by a distance that is at least sufficient to achieve a breakdown voltage between the front second gate component and the source. The front second gate component extends between two-tenths (0.2) and two (2) micrometers in a first dimension and between two-tenths (0.2) and two (2) micrometers in a second dimension. The volume of semiconductor material may include an N-type epitaxial semiconductor material, the source may include an N+ material, the drain may include an N+ substrate material, and the first gate and the second gate may include a P+ material. The planar JFET may further include a first electrical terminal provided on the source, a second electrical terminal provided on the drain, a third electrical terminal provided on the left first gate component, a fourth electrical terminal provided on the right first gate component, and a fifth electrical terminal provided on the rear second gate component.

In another example, a planar JFET with enhanced channel control may include a volume of semiconductor material, a source, a drain, a channel, a first gate, and a second gate. The volume of semiconductor material may include a first end, a second end, a first side, and a second side. The source may be located at the first end of the semiconductor material, the drain may be located at the second end and spaced apart from and opposite the source, and the channel may extend between the source and the drain through the semiconductor material. The first gate may include a left first gate component located at the first end and the first side of the volume of semiconductor material and spaced apart from the source, and a right first gate component located at the first end and the second side of the volume of semiconductor material and spaced apart from the source. The second gate may include a front second gate component and a rear second gate component. The front second gate component may be located spaced apart from and between the source and the drain and surrounded in two dimensions by the volume of semiconductor material, and the front second gate component may be located at least partially between the left first gate component and the drain and at least partially between the right first gate component and the drain, and may include a first side and a second side, and the left first gate component extends at least partially along the first side of the front second gate component and the right first gate component extends at least partially along the second side of the front second gate component, and the front first gate component further includes an extension in a third dimension through the volume of semiconductor material. The rear second gate component may extend from the extension of the front second gate component to a surface at the first end of the volume of semiconductor material. The front second gate component may divide the channel into a first non-linear channel path and a second non-linear channel path. The first non-linear channel path may extend from the source toward the drain, turn and extend along the front second gate component in a first direction, and turn around the first side of the front second gate component and extend to the drain, wherein the front second gate component and the left first gate component cooperate to control a first electrical current flowing through the first non-linear channel path. The second non-linear channel path may extend from the source toward the drain, turn and extend along the front second gate component in a second direction, and turn around the second side of the front second gate component and extend to the drain, wherein the front second gate component and the right first gate component cooperate to control a second electrical current flowing through the second non-linear channel path.

The preceding example may further include any one or more of the following features. The front second gate component may be spaced apart from the source by a distance that is at least sufficient to achieve a breakdown voltage between the front second gate component and the source. The front second gate component extends between two-tenths (0.2) and two (2) micrometers in a first dimension and between two-tenths (0.2) and two (2 ) micrometers in a second dimension. The volume of semiconductor material may include an N-type epitaxial semiconductor material, the source may include an N+ material, the drain may include an N+ substrate material, and the first gate and the second gate may include a P+ material. The planar JFET may further include a first electrical terminal provided on the source, a second electrical terminal provided on the drain, a third electrical terminal provided on the left first gate component, a fourth electrical terminal provided on the right first gate component, and a fifth electrical terminal provided on the rear second gate component.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of a first example of a planar JFET with enhanced channel control;

FIG. 2 is a cross-sectional isometric view of the JFET of FIG. 1;

FIG. 3 is a plan view of the JFET of FIG. 1;

FIG. 4 is a flowchart of operations in a first example of a method of manufacturing a planar JFET with enhanced channel control, such as the JFET of FIG. 1;

FIG. 5A is a cross-sectional elevation view of the result of an operation in the method of FIG. 4, wherein a P+ implantation for a second, buried gate in an N-type epitaxial layer on an N+ substrate is shown;

FIG. 5B is a cross-sectional elevation view of the result of an operation in the method of FIG. 4, wherein an N+ implantation for a source and a P+ implantation for a first gate is shown;

FIG. 5C is a cross-sectional elevation view of the result of an operation in the method of FIG. 5, wherein the addition of electrical terminals is shown;

FIG. 6 is a cross-sectional elevation view of a second example of a planar JFET with enhanced channel control;

FIG. 7 is a cross-sectional isometric view of the JFET of FIG. 6;

FIG. 8 is a flowchart of operations in a second example of a method of manufacturing a planar JFET with enhanced channel control, such as the JFET of FIG. 6;

FIG. 9A is a cross-sectional elevation view of the result of an operation in the method of FIG. 8, wherein a P+ implantation for a second, buried gate in an N-type epitaxial layer on an N+ substrate is shown;

FIG. 9B is a cross-sectional elevation view of the result of an operation in the method of FIG. 8, wherein an N+ implantation for a source and a P+ implantation for a first gate is shown; and

FIG. 9C is a cross-sectional elevation view of the result of an operation in the method of FIG. 8, wherein the addition of electrical terminals is shown.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, any similarity in numbering does not necessarily mean that the structures or components are necessarily identical in size, composition, configuration, or any other property.

Terms of relative location and direction (e.g., above, below, left, right, upper, lower, front, rear) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

Thus, it will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a planar JFET with enhanced channel control, and a method of making a planar JFET with enhanced channel control. Broadly, a second gate component is configured and positioned to divide a channel into multiple paths for electrical current to flow between the source and the drain. Examples advantageously provide improved performance, including improved gate control and a lower electric resistance to current flow through the semiconductor material between the source and drain when the device is “on,” i.e., examples provide a lower RDS (on) compared to that of a typical JFET.

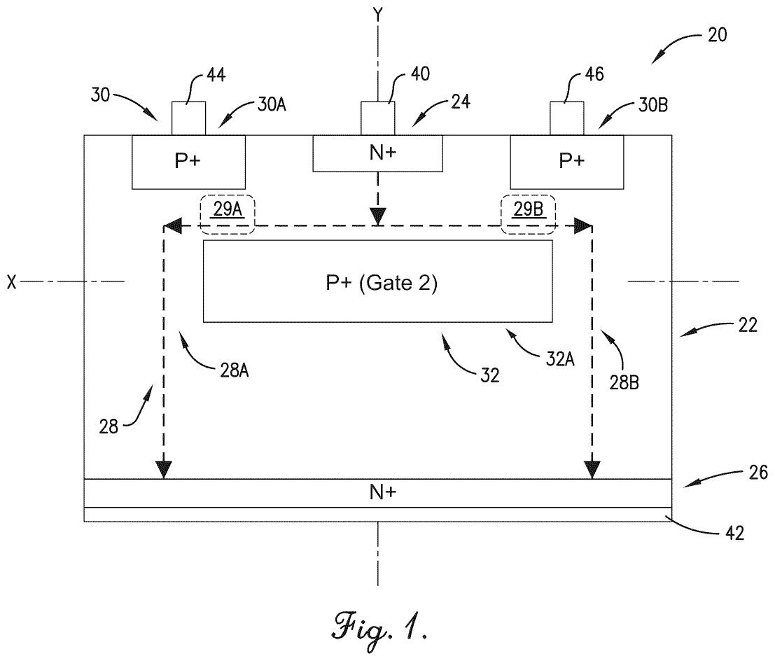

Referring to FIGS. 1-3, a first example of a planar JFET 20 with enhanced channel control may include a volume of semiconductor material 22, a source 24, a drain 26, a channel 28, a first gate 30, and a second gate 32. The relative locations of these components are described below with respect to the X, Y, and Z axes, or dimensions, overlaid onto FIGS. 1-3. It will be understood that these axes, or dimensions, like other terms of relative location or direction, are used to facilitate the present description with reference to the figures and, unless expressly stated, are not meant to be limiting with regard to location, direction, or overall orientation.

The volume of semiconductor material 22 may include a first end, a second end, a first side, and a second side. The first end may be spaced apart from the second end along the Y axis, and the first side may be spaced apart from the second side along the X axis. The semiconductor material 22 may be or include an N-type epitaxial semiconductor material. The source 24 may be located at or near the first end of the semiconductor material 22 and provide an entrance for the majority charge carriers (e.g., electrons for N-channel) into the channel 28. The source 24 may be constructed from or include an N+ material. The drain 26 may be located at or near the second end of the semiconductor material 22, spaced apart from and opposite the source 24, and provide an exit for the majority charge carriers from the channel 28. According to some aspects, however, the drain may alternatively be located relative to the volume of semiconductor material 22 (such as on the same end as the source). The drain 24 may be constructed from or include an N+ substrate material. The channel 28 may be provided by the semiconductor material 22 between the source 24 and the drain 26 and through which the majority charge carriers move, i.e., through which electric current flows. It will be appreciated that the majority charge carriers, which are, in this present example, electrons, flow from the source 24 to the drain 26, and the conventional current, Id, flows from the drain 26 to the source 24. As discussed below, the position of the second gate 32 between the source 24 and the drain 26 results in the channel 28 being divided into two paths 28A, 28B which extend around opposite sides of the second gate 32.

The first gate 30 may include a left first gate component 30A and a right first gate component 30B. The left first gate component 30A may be generally located at the first end and the first side of the semiconductor material 22 adjacent to and spaced apart from the source 24, The right first gate component 30B may be generally located at the first end and the second side of the semiconductor material 22 adjacent to and spaced apart from the source 24. The left and right first gate components 30A, 30B may be constructed from or include P+ material. As discussed below, the left and right first gate components 30A, 30B may be electrically connected to the same voltage source.

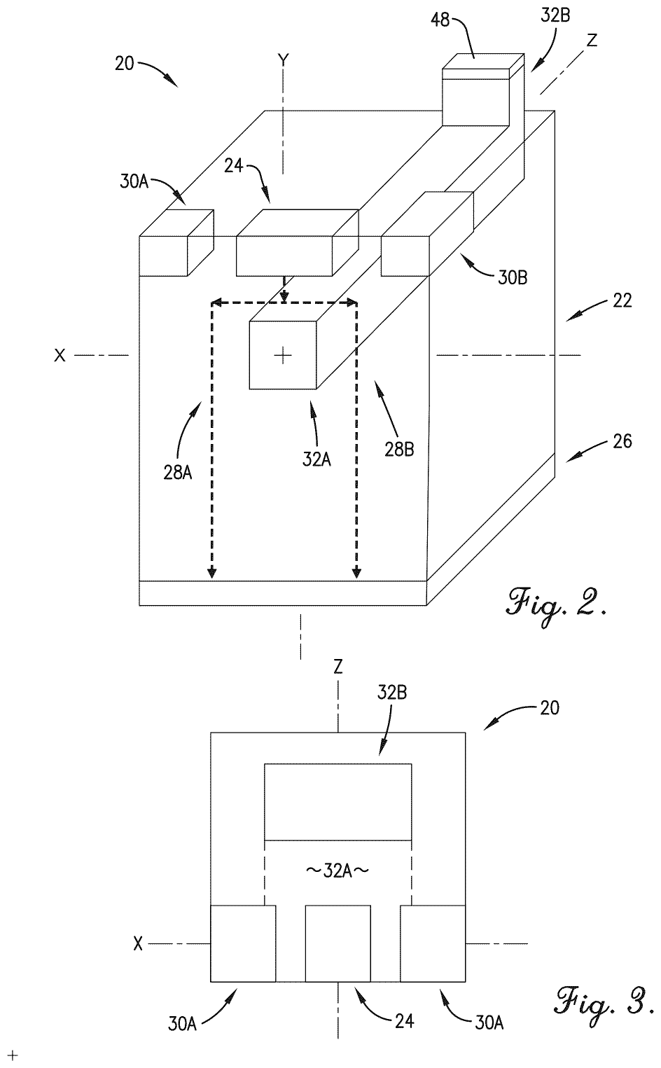

The second gate 32 may include a front second gate component 32A and a rear second gate component 32B. The front second gate component 32A may be embedded, or “buried,” within the semiconductor material 22, generally between the first and second ends and between the first and second sides, so as to be positioned between and spaced apart from the source 24 and the drain 26 and at least partly between (in the vertical direction) and spaced apart from the left and right first gate components 30A, 30B and the drain 26. The cross-sectional X, Y dimensions of the front second gate component 32A may be between two-tenths (0.2) and two (2) micrometers in width and between two-tenths (0.2) and two (2) micrometers in height. As seen in FIGS. 2 and 3, the front second gate component 32A may include an extension along a Z axis through the semiconductor material 22. The rear second gate component 32B may be located at an end of the extension of the front second gate component 32A, and extend at an angle from the front second gate component 32A (e.g., ninety (90) degrees) to a surface of the volume of semiconductor material 22 to provide an exposed surface for coupling with an electrical terminal.

Thus, the front second gate component 32A may be surrounded in a first dimension, X, and a second dimension, Y, by the semiconductor material 22 and extend along the Z axis through the semiconductor material 22, and the rear second gate component 32B may extend from the end of the front second gate component 32A at an angle relative to the Z axis to a surface of the volume of semiconductor material 22. The front and rear second gate components 32A, 32B may be constructed from or include a P+ material. In operation, the front second gate component 32A may function as the primary shielding and gate controlling node.

The channel 28 initially extends from the source 24 toward the drain 26, i.e., in the direction of the second end of the semiconductor material 22. The position of the front second gate component 32A beneath the source 24 divides the channel 28 into the first and second non-linear channel paths 28A, 28B. The first channel path 28A turns and extends in the direction of the first side of the semiconductor material 22 and runs between the left first gate component 30A and a first side of the front second gate component 32A, before turning around the first side of the front second gate component 32A and extending toward the drain 26. The left first gate component 30A and the left first side of the second gate component 32A cooperate to provide a first control point 29A for controlling an electrical current flowing through the first channel path 28A. The second channel path 28B turns and extends in the direction of the second side of the semiconductor material 22 and runs between the right first gate component 30A and a second side of the front second gate component 32A, before turning around the second side of the front second gate component 32A and extending toward the drain 26. The right first gate component 30B and the second side of the second gate component 32A cooperate to provide a second control point 29B for controlling an electrical current flowing through the second channel path 28B. The distance between the left and right first gate components 30A, 30B and the front second gate component 32A, i.e., the width of the first and second channel paths 28A, 28B, may be sufficient to achieve the breakdown voltage (BVgs) between the front second gate component 32A and the source 24.

The source 24 may include a first electrical terminal 40, the drain 26 may include a second electrical terminal 42, the left first gate component 30A may include a third electrical terminal 44, the right first gate component 30B may include a fourth electrical terminal 46, and the rear second gate component 32B may include a fifth electrical terminal 48 (seen in FIG. 2) for facilitating connections to appropriate voltage sources, as described below.

In operation, an input voltage, Vds, may be applied across the first and second electrical terminals 40, 42 to cause electron drift/movement from the source 24 to the drain 26; and a control voltage, Vgs, may be applied across the first and third electrical terminals 40, 44 to control the width of the depletion region at the P-N junctions where the charge carriers of the P- and N-type materials diffuse into each other, which “depletes” the available concentrations of majority charge carrier in each material, and thereby control the current, Id, from the drain 26 to source 24. Thus, the source 24, the first gate 30, and the second gate 32 may cooperate under Vgs to control the current, Id, through the channel 28. If Vgs=0 V and Vds>0 V, electrons drift, or move, from the source to the drain, resulting in a current, Id, from the drain 26 to the source 24, and increased depletion regions at the P-N junctions. If Vds=pinch-off voltage (Vp), then the depletion regions increase in size and grow sufficiently close to each other across the channel 28 that the current, Id, through the channel cannot increase and so is at its maximum, Id=(max drain current (Idss)). In the present examples, the shielding of the source 24 by the lower second gate component 32A reduces a reverse bias leakage current and provides a higher breakdown voltage (BVgs) for the JFET 20. Further, the first and second gates 30, 32 cooperate to create separate control points 29A, 29B, for controlling current flow through the channel paths 28A, 28B.

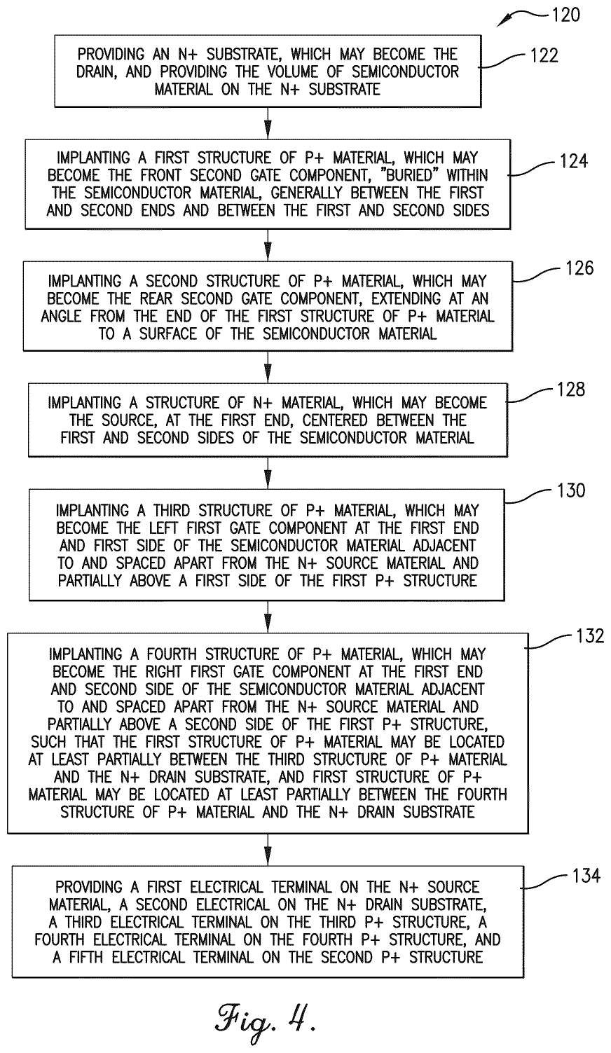

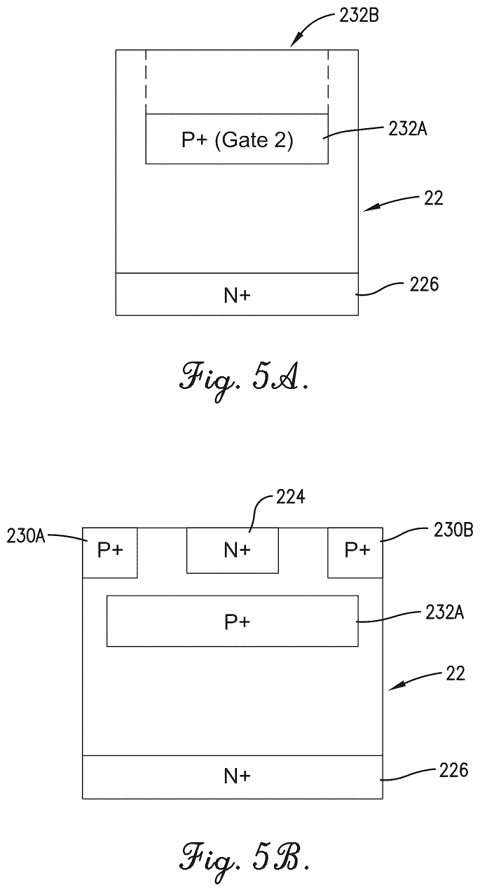

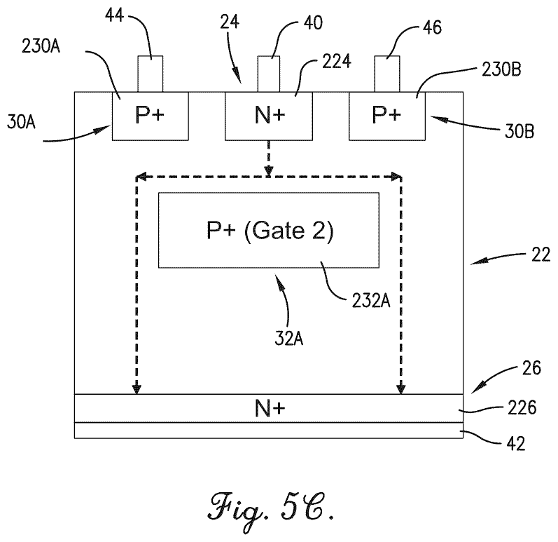

Referring to FIG. 4, a first example of a method 120 of making a planar JFET with enhanced channel control, such as the planar JFET 20 described above, may include the operations set forth below. Referring additionally to FIGS. 5A-C, example results are shown of the operations of the method 120, which may be stages in the manufacture of the planar JFET 20.

An N+ substrate 226, which may become the drain 26, may be provided, and the volume of semiconductor material 22 may be grown or otherwise provided on the N+ substrate 226, as shown in operation 122 and seen in FIG. 5A. The N+ substrate 226 may be or include a 4H—SiC material, and the semiconductor material 22 may be or include an N-type epitaxial semiconductor material. The volume of semiconductor material 22 may include a first end, a second end, a first side, and a second side, and the N+ substrate 226 may be located at the second cnd.

A first structure of P+ material 232A, which may become the front second gate component 32A, may be implanted (using, e.g., an ion implanter) or otherwise provided, or “buried,” within the volume of semiconductor material 22, generally between the first and second ends and between the first and second sides, as shown in operation 124 and also seen in FIG. 5A. The first structure of P+ material 232A, may be surrounded (as seen in cross-sectional elevation view) in a first dimension, X, and a second dimension, Y, by the semiconductor material 22. The cross-sectional (X, Y) dimensions of the first structure of P+ material 232A may be between two-tenths (0.2) and two (2) micrometers in width and between two-tenths (0.2) and two (2) micrometers in height. The first structure of P+ material 232A may include an extension along a Z axis through the semiconductor material 22.

A second structure of P+ material 232B, which may become a rear second gate component 32B, may be implanted or otherwise provided so as to be located at an end of the extension of the first structure of P+ material 232A, and extend at an angle from the end of the first structure of P+ material 232A (e.g., ninety (90) degrees) to a surface of the volume of semiconductor material 22 to provide an exposed surface for coupling with an electrical terminal, as shown in operation 126 and also seen (in broken line) in FIG. 5A (and seen as the resulting rear second gate component 32B in FIG. 2). Thus, the first structure of P+ material 232A may be surrounded in a first dimension, X, and a second dimension, Y, by the semiconductor material 22 and extend along a Z axis through the semiconductor material 22, and the second structure of P+ material 232B may extend at an angle relative to the Z axis to the surface of the volume of semiconductor material 22.

A structure of N+ material 224, which may become the source 24, may be implanted or otherwise provided at or near the first end, approximately centered between the first and second sides of the semiconductor material 22, as shown in step 128 and seen in FIG. 5B.

A third structure of P+ material 230A, which may become the first component 30A of the first gate 30, may be implanted in the volume of semiconductor material 22, as shown in operation 130 and also seen in FIG. 5B. The third structure of P+ material 230A may be generally located at the first end and the first side of the semiconductor material 22 spaced apart from the N+ source material 224 and partially above a first side of the first P+ structure 232A.

A fourth structure of P+ material 230B, which may become the second component 30B of the first gate 30, may be implanted in the volume of semiconductor material 22, as shown in step 132 and also seen in FIG. 5B. The fourth structure of P+ material 230B may be generally located at the first end and the second side of the semiconductor material 22 spaced apart the N+ source material 224 and partially above a second side of the first P+ structure 232A. Thus, the first structure of P+ material 232A may be located at least partially between the third structure of P+ material 230A and the N+ drain substrate 226, and the first structure of P+ material 232B may be located at least partially between the fourth structure of P+ material 232B and the N+ drain substrate 226.

In the finished JFET 20, the first structure of P+ material 232A (i.e., the front second gate component 32A), may function as the primary shielding and gate controlling node. The positioning of the first structure of P+ material 232A beneath the N+ source material 224 provides a “shield,” and divides the channel 28 into first and second nonlinear channel paths 28A, 28B which extend in opposite directions before turning toward the N+ drain substrate 226, as discussed above. Further, the third P+ structure 230A (i.e., the left first gate component 30A) and the first side of the first P+ structure 232A cooperate to provide a first control point 29A for controlling an electrical current flowing through the first channel path 28A, and the fourth P+ structure 230B (i.e., the right first gate component 230B) and the second side of the first P+ structure 232A cooperate to provide a second control point 29B for controlling an electrical current flowing through the second channel path 28B, as discussed above.

The distance between the third and fourth P+ structures 230A, 230B and the first P+ structure 232A, i.e., the width of the first and second channel portions 28A, 28B, may be sufficient to achieve the breakdown voltage (BVgs) between the front second gate component 32A and the source 24.

A first electrical terminal 40 may be provided on the N+ source material 224, a second electrical terminal 42 may be provided on the N+ drain substrate 226, a third electrical terminal 44 may be provided on the third P+ structure 230A, a fourth electrical terminal 46 may be provided on the fourth P+ structure 230B, and a fifth electrical terminal 48 may be provided on the second P+ structure 232B (seen in FIG. 2), as shown in step 134 and seen in FIG. 5C, for facilitating connections to appropriate voltage sources, as described above.

Additional processing may be performed as desired.

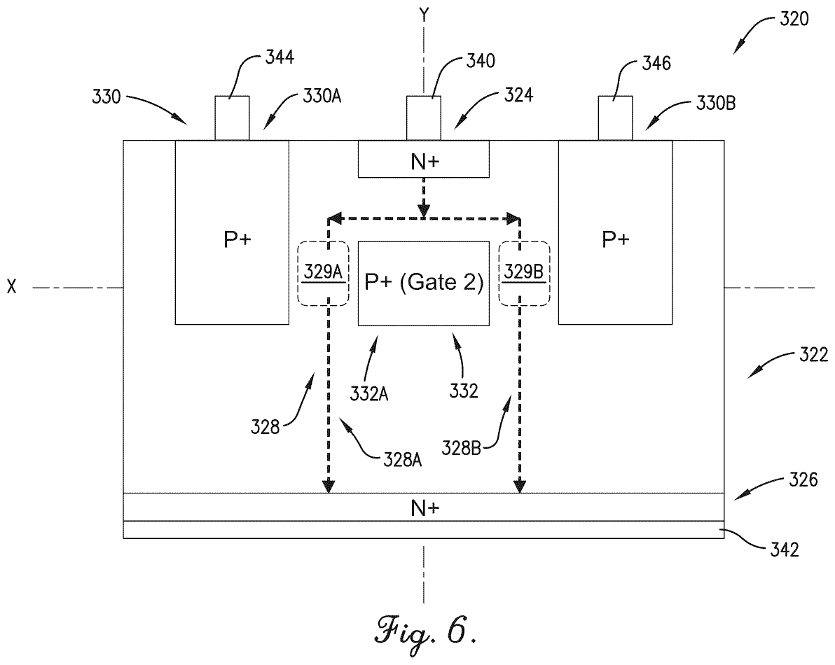

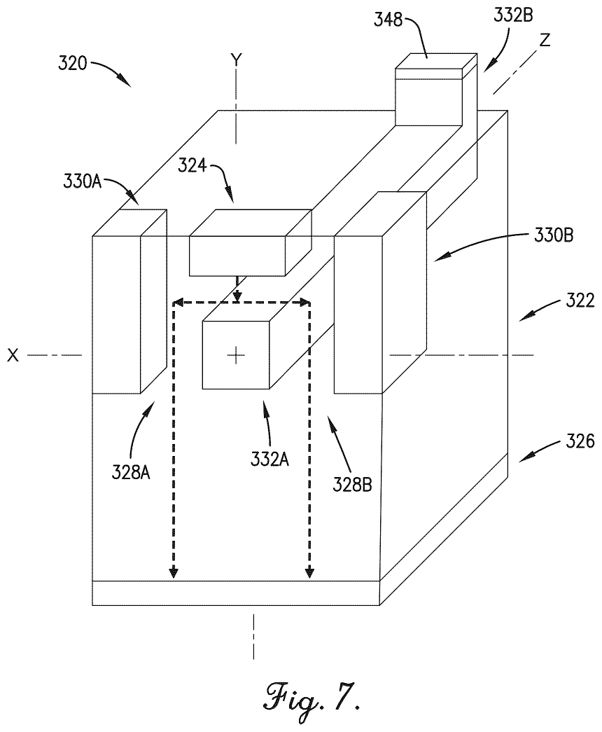

Referring to FIGS. 6 and 7, a second example of a planar JFET 320 with a buried gate may include a volume of semiconductor material 322, a source 324, a drain 326, a channel 328, a first gate 330, and a second gate 332. The relative locations of these components are described below with respect to the X, Y, and Z axes, or dimensions, overlaid onto FIGS. 6 and 7. It will be understood that these axes, or dimensions, like other terms of relative location or direction, are used to facilitate the present description with reference to the figures and, unless expressly stated, are not meant to be limiting with regard to location, direction, or overall orientation.

The volume of semiconductor material 322 may include a first end, a second end, a first side, and a second side. The first end may be spaced apart from the second end along the Y axis, and the first side may be spaced apart from the second side along the X axis. The semiconductor material 322 may be or include an N-type epitaxial semiconductor material. The source 324 may be located at or near the first end of the semiconductor material 322 and provide an entrance for the majority charge carriers (e.g., electrons for N-channel) into the channel 328. The source 324 may be constructed from or include an N+ material. The drain 326 may be located at or near the second end of the semiconductor material 322, spaced apart from and opposite the source 324, and provide an exit for the majority charge carriers from the channel 328. According to some aspects, however, the drain may alternatively be located relative to the volume of semiconductor material 22 (such as on the same end as the source). The drain 324 may be constructed from or include an N+ substrate material. The channel 328 may be provided by the semiconductor material 322 between the source 324 and the drain 326 and through which the majority charge carriers move, i.e., through which electric current flows. It will be appreciated that the majority charge carriers, which are, in this present example, electrons, flow from the source 324 to the drain 326, and the conventional current, Id, flows from the drain 326 to the source 324. As discussed below, the position of the second gate 332 between the source 324 and the drain 326 results in the channel 328 being divided into two paths 328A, 328B which extend around opposite sides of the second gate 332.

The first gate 330 may include a left first gate component 330A and a right first gate component 330B. The left first gate component 330A may be generally located at the first end and the first side of the semiconductor material 322 spaced apart from the source 324. The right first gate component 330B may be generally located at the first end and second side of the semiconductor material 322 spaced apart from the source 324. The left and right first gate components 330A, 330B may be constructed from or include P+ material. As discussed below, the left and right first gate components 330A, 330B may be electrically connected to the same voltage source.

The second gate 332 may include a front second gate component 332A and a rear second gate component 332B. The front second gate component 332A may be located, or “buried” within the semiconductor material 322, generally between the first and second ends and between the first and second sides, so as to be positioned between and spaced apart from the source 324 and the drain 326 and at least partly between (in the lateral direction) and spaced apart from the first and right first gate components 330A, 330B. The cross-sectional (X, Y) dimensions of the front second gate component 332A may be between two-tenths (0.2) and two (2) micrometers in width and between two-tenths (0.2) and two (2) micrometers in height. As seen in FIGS. 6 and 7, the front second gate component 332A may include an extension along a Z axis through the semiconductor material 322. The rear second gate component 332B may be located at an end of the extension of the front second gate component 332A, and extend at an angle from the front second gate component 332A (e.g., ninety (90) degrees) to a surface of the volume of semiconductor material 322 to provide an exposed surface for coupling with an electrical terminal.

Thus, the front second gate component 332A may be surrounded in a first dimension, X, and a second dimension, Y, by the semiconductor material of the channel and extend along the Z axis through the semiconductor material 322. The rear second gate component 332B may extend from the end of the front second gate component 332A at an angle relative to the Z axis to the surface of the volume of semiconductor material 322. The front and rear second gate components 332A, 332B may be constructed from or include a P+ material. In operation, the front second gate component 332A may function as the primary shielding and gate controlling node.

The channel 328 initially extends from the source 324 toward the drain 326 (i.e., in the direction of the second end of the semiconductor material 322). The position of the front second gate component 332A beneath the source divides the channel 328 into the first and second channel paths 328A, 328B. The first channel path 328A turns and extends in the direction of the first side of the semiconductor material before turning around the first side of the front second gate component 332A and extending between the left first gate component 330A and the first side of the front second gate component 332A and toward the drain 326. The left first gate component 330A and the first side of the front second gate component 332A cooperate to provide a first control point 329A for controlling an electrical current flowing through the first channel path 328A. The second channel path 328B turns and extends in the direction of the second side of the semiconductor material 322 before turning around the second side of the front second gate component 332A and extending between the right first gate component 330A and the second side of the front second gate component 332A and toward the drain 326. The left first gate component 330A and the second side of the second gate component 332A cooperate to provide a second control point 329B for controlling an electrical current flowing through the second channel path 328B. The distance between the first and right first gate components 330A, 330B and the front second gate component 332A, i.e., the width of the first and second channel paths 328A, 328B may be sufficient to achieve the breakdown voltage (BVgs) between the front second gate component 332A and the source 324.

The source 324 may include a first electrical terminal 340, the drain 326 may include a second electrical terminal 342, the left first gate component 330A may include a third electrical terminal 344, the right first gate component 330B may include a fourth electrical terminal 346, and the rear second gate component 332B may include a fifth electrical terminal 348 for facilitating connections to appropriate voltage sources, as described below.

In operation, an input voltage, Vds, may be applied across the first and second electrical terminals 340, 342 to cause electron drift/movement from the source 324 to the drain 326; and a control voltage, Vgs, may be applied across the first and third electrical terminals 340, 344 to control the width of the depletion region at the P-N junctions where the charge carriers of the P-and N-type materials diffuse into each other, which “depletes” the available concentrations of majority charge carrier in each material, and thereby control the current, Id, from the drain 326 to source 324. Thus, the source 324, the first gate 330, and the second gate 332 may cooperate under Vgs to control the current, Id, through the channel 328. If Vgs=0 V and Vds>0 V, electrons drift, or move, from the source to the drain, resulting in a current, Id, from the drain 326 to the source 324, and increased depletion regions at the P-N junctions. If Vds=pinch-off voltage (Vp), then the depletion regions increase in size and grow sufficiently close to each other across the channel 328 that the current, Id, through the channel cannot increase and so is at its maximum, Id=(max drain current (Idss)). In the present examples, the shielding of the source 324 by the lower second gate component 332A reduces a reverse bias leakage current and provides a higher breakdown voltage (BVgs) for the JFET 320. The first and second gates 330, 332 cooperate to create separate control points 329A, 329B, for controlling current flow through the channel paths 328A, 328B.

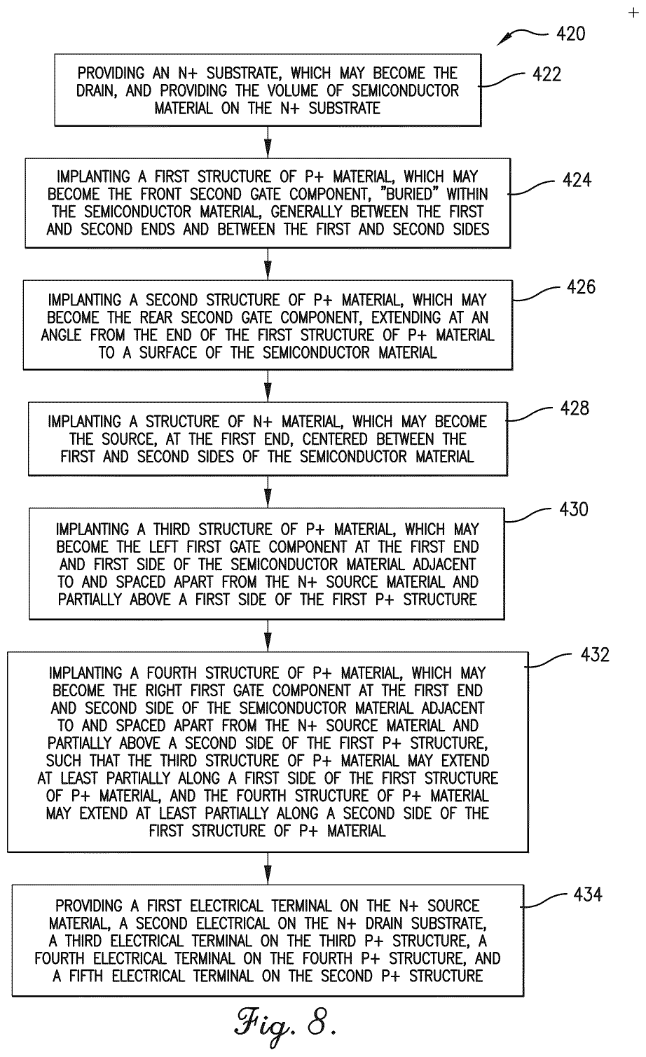

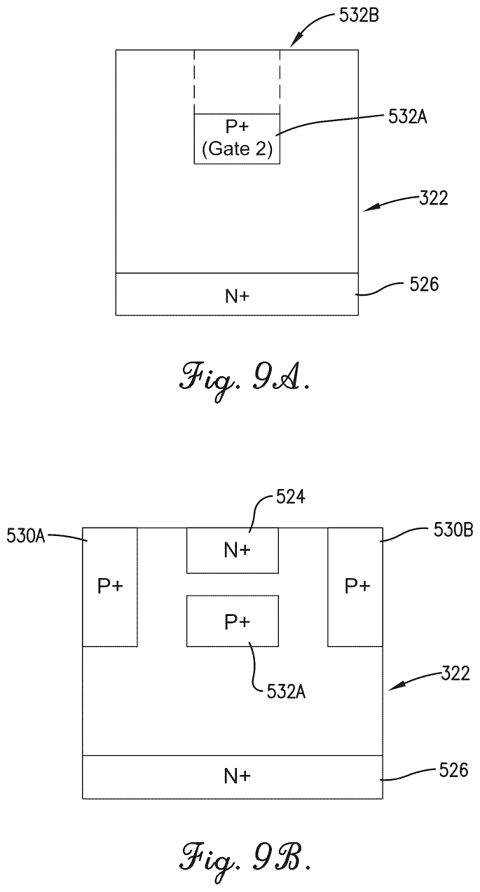

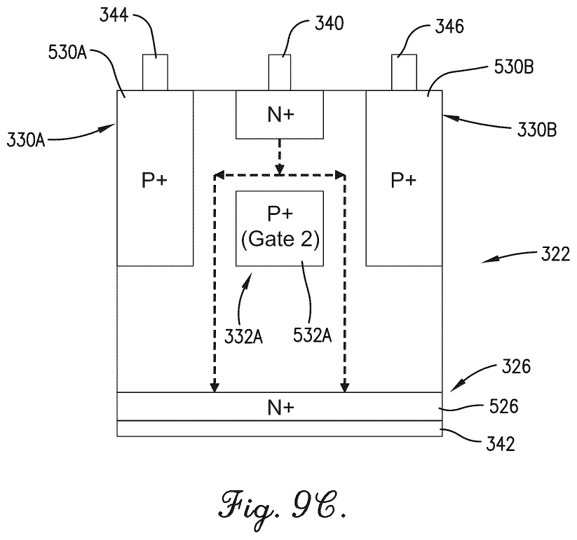

Referring to FIG. 8, a second example of a method 420 of making a planar JFET with enhanced channel control, such as the planar JFET 320 described above, may include the operations set forth below. Referring additionally to FIGS. 9A-C, example results are shown of the operations of the method 420, which may be stages in the manufacture of the planar JFET 320.

An N+ substrate 526, which may become the drain 326, may be provided, and the volume of semiconductor material 322 may be grown or otherwise provided on the N+ substrate 526, as shown in 422 and seen in FIG. 9A. The N+ substrate 526 may be or include a 4H—SiC material, and the semiconductor material 322 may be or include an N-type epitaxial semiconductor material. The volume of semiconductor material 322 may include a first end, a second end, a first side, and a second side, and the N+ substrate 526 may be located at the second end.

A first structure of P+ material 532A, which may become the front second gate component 332A, may be implanted (using, e.g., an ion implanter) or otherwise provided, or “buried,” within the volume of semiconductor material 322, generally between the first and second ends and between the first and second sides, as shown in operation 424 and also seen in FIG. 9A. The first structure of P+ material 532A, may be surrounded (as seen in cross-sectional elevation view) in a first dimension, X, and a second dimension, Y, by the semiconductor material 322. The cross-sectional (X, Y) dimensions of the first structure of P+ material 532A may be between two-tenths (0.2) and two (2) micrometers in width and between two-tenths (0.2) and two (2) micrometers in height. The first structure of P+ material 532A may include an extension along a Z axis through the semiconductor material 322.

A second structure of P+ material 532B, which may become a rear second gate component 332B, may be implanted or otherwise provided so as to be located at an end of the extension of the first structure of P+ material 532A along the Z-axis. The second structure of P+ material 532B may extend at an angle from the end of the first structure of P+ material 532A (e.g., ninety (90) degrees) to a surface of the volume of semiconductor material 322 to provide an exposed surface for coupling with an electrical terminal, as shown in operation 426 and also seen (in broken line) in FIG. 9A (and seen as the resulting rear second gate component 332B in FIG. 7). Thus, the first structure of P+ material 532A may be surrounded in a first dimension, X, and a second dimension, Y, by the semiconductor material 322 and extend along a Z axis through the semiconductor material 322; and the second structure of P+ material 532B may extend at an angle relative to the Z axis to the surface of the volume of semiconductor material 322.

A structure of N+ material 524, which may become the source 324, may be implanted or otherwise provided at or near the first end, centered between the first and second sides of the semiconductor material 322, as shown in step 428 and seen in FIG. 9B.

A third structure of P+ material 530A, which may become the left first gate component 330A of the first gate 330, may be implanted in the volume of semiconductor material 322, as shown in step 430 and also seen in FIG. 9B. The third structure of P+ material 530A may be generally located at the first end and the first side of the semiconductor material 322 adjacent to and spaced apart from the N+ source material 524.

A fourth structure of P+ material 530B, which may become the right second gate component 330B of the first gate 330, may be implanted in the volume of semiconductor material 322, as shown in step 432 and also seen in FIG. 9B. The fourth structure of P+ material 530B may be generally located at the first end and the second side of the semiconductor material 322 adjacent to and spaced apart the N+ source material 524. Thus, the third structure of P+ material 530A may extend at least partially along a first side of the first structure of P+ material 532A, and the fourth structure of P+ material 530B may extend at least partially along a second side of the first structure of P+ material 532A.

In the finished JFET 320, the first structure of P+ material 532A (i.e., the front second gate component 332A), may function as the primary shielding and gate controlling node. The positioning of the first structure of P+ material 232A beneath the N+ source material 524 provides a “shield,” and divides the channel 28 into first and second channel paths 328A, 328B which extend in opposite directions before turning toward the N+ drain substrate 526, as discussed above. Further, the third P+ structure 530A (i.e., the left first gate component 330A) and the first side of the first P+ structure 532A cooperate to provide a first control point 329A for controlling an electrical current flowing through the first channel path 328A, and the fourth P+ structure 530B (i.e., the right first gate component 530B) and the second side of the first P+ structure 532A cooperate to provide a second control point 329B for controlling an electrical current flowing through the second channel path 328B, as discussed above.

The distance between the third and fourth P+ structures 530A, 530B and the first P+ structure 532A, i.e., the width of the first and second channel portions 328A, 328B, may be sufficient to achieve the breakdown voltage (BVgs) between the front second gate component 332A and the source 324.

A first electrical terminal 340 may be provided on the N+ source material 524, a second electrical terminal 342 may be provided on the N+ drain substrate 526, a third electrical terminal 344 may be provided on the third P+ structure 530A, a fourth electrical terminal 346 may be provided on the fourth P+ structure 530B, and a fifth electrical terminal 348 may be provided on the second P+ structure 532B (seen in FIG. 7), as shown in operation 434 and seen in FIG. 9C, for facilitating connections to appropriate voltage sources, as described above.

Additional processing may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right or left side of a volume of semiconductor material may be to the conceptual limit of a particular unit cell and not to an actual physical end of the material.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A planar junction field-effect transistor with enhanced channel control, the planar junction field-effect transistor comprising:
a source;
a drain spaced apart from the source;
a channel extending between the source and the drain;
a first gate including a left first gate component and a right first gate component;
a second gate including a front second gate component located between and spaced apart from the source and the drain and including a first side and a second side,
wherein the front second gate component divides the channel into a first non-linear channel path and a second non-linear channel path, such that—
the first non-linear channel path extends from the source toward the drain, turns and extends along the front second gate component in a first direction, and turns around the first side of the front second gate component and extends to the drain, wherein the front second gate component and the left first gate component cooperate to control a first electrical current flowing through the first non-linear channel path, and
the second non-linear channel path extends from the source toward the drain, turns and extends along the front second gate component in a second direction, and turns around the second side of the front second gate component and extends to the drain, wherein the front second gate component and the right first gate component cooperate to control a second electrical current flowing through the second non-linear channel path.

2. The planar junction field-effect transistor of claim 1, wherein the front second gate component is located at least partially between the left first gate component and the drain, and the front second gate component is located at least partially between the right first gate component and the drain.

3. The planar junction field-effect transistor of claim 1, wherein the left first gate component extends at least partially along the first side of the front second gate component, and the right first gate component extends at least partially along the second side of the front second gate component.

4. The planar junction field-effect transistor of claim 1, wherein the front second gate component is spaced apart from the source by a distance that is at least sufficient to achieve a breakdown voltage between the front second gate component and the source.

5. The planar junction field-effect transistor of claim 1, wherein the front second gate component extends between two-tenths (0.2) and two (2) micrometers in a first dimension and between two-tenths (0.2) and two (2) micrometers in a second dimension.

6. The planar junction field-effect transistor of claim 1, wherein—
the source includes an N+ material;
the drain includes an N+ substrate material; and
the first gate and the second gate include a P+ material.

7. The planar junction field-effect transistor of claim 1, wherein the front second gate component includes an extension in a third dimension, and the second gate includes a rear second gate component extending at an angle from the extension of the front second gate component.

8. The planar junction field-effect transistor of claim 7, further including—
a first electrical terminal provided on the source;
a second electrical terminal provided on the drain;
a third electrical terminal provided on the left first gate component;
a fourth electrical terminal provided on the right first gate component; and
a fifth electrical terminal provided on the rear second gate component.

9. A planar junction field-effect transistor with enhanced channel control, the planar junction field-effect transistor comprising:
a volume of semiconductor material including a first end, a second end, a first side, and a second side;
a source located at the first end of the volume of semiconductor material;
a drain located at the second end of the volume of semiconductor material and spaced apart from and opposite the source;
a channel extending between the source and the drain through the volume of semiconductor material;
a first gate including—
a left first gate component located at the first end and the first side of the volume of semiconductor material and spaced apart from the source, and
a right first gate component located at the second end and the second side of the volume of semiconductor material and spaced apart from the source; and
a second gate including—
a front second gate component located spaced apart from and between the source and the drain and surrounded in two dimensions by the volume of semiconductor material, the front second gate component being located at least partially between the left first gate component and the drain and at least partially between the right first gate component and the drain, the front second gate component including a first side and a second side and an extension in a third dimension through the volume of semiconductor material, and
a rear second gate component extending from the extension of the front second gate component to a surface at the first end of the volume of semiconductor material,
wherein the front second gate component divides the channel into a first non-linear channel path and a second non-linear channel path, such that—
the first non-linear channel path extends from the source toward the drain, turns and extends along the front second gate component in a first direction, and turns around the first side of the front second gate component and extends to the drain, wherein the front second gate component and the left first gate component cooperate to control a first electrical current flowing through the first non-linear channel path, and
the second non-linear channel path extends from the source toward the drain, turns and extends along the front second gate component in a second direction, and turns and around the second side of the front second gate component and extends to the drain, wherein the front second gate component and the right first gate component cooperate to control a second electrical current flowing through the second non-linear channel path.

10. The planar junction field-effect transistor of claim 9, wherein the front second gate component is spaced apart from the source by a distance that is at least sufficient to achieve a breakdown voltage between the front second gate component and the source.

11. The planar junction field-effect transistor of claim 9, wherein the front second gate component extends between two-tenths (0.2) and two (2) micrometers in a first dimension and between two-tenths (0.2) and two (2) micrometers in a second dimension.

12. The planar junction field-effect transistor of claim 9, wherein—
the volume of semiconductor material includes an N-type epitaxial semiconductor material;
the source includes an N+ material;
the drain includes an N+ substrate material; and
the first gate and the second gate include a P+ material.

13. The planar junction field-effect transistor of claim 9, further including—
a first electrical terminal provided on the source;
a second electrical terminal provided on the drain;
a third electrical terminal provided on the left first gate component;
a fourth electrical terminal provided on the right first gate component; and
a fifth electrical terminal provided on the rear second gate component.

14. A planar junction field-effect transistor with enhanced channel control, the planar junction field-effect transistor comprising:
a volume of semiconductor material including a first end, a second end, a first side, and a second side;
a source located at the first end of the volume of semiconductor material;
a drain located at the second end of the volume of semiconductor material and spaced apart from and opposite the source;
a channel extending between the source and the drain through the volume of semiconductor material;
a first gate including—
a left first gate component located at the first end and the first side of the volume of semiconductor material and spaced apart from the source, and
a right first gate component located at the first end and the second side of the volume of semiconductor material and spaced apart from the source; and
a second gate including—
a front second gate component located spaced apart from and between the source and the drain and surrounded in two dimensions by the volume of semiconductor material, the front second gate component including a first side and a second side, and the left first gate component extends at least partially along the first side of the front second gate component, and the right first gate component extends at least partially along the second side of the front second gate component, the front second gate component further including an extension in a third dimension through the volume of semiconductor material and
a rear second gate component extending from the extension of the front second gate component to a surface at the first end of the volume of semiconductor material,
wherein the front second gate component divides the channel into a first non-linear channel path and a second non-linear channel path, such that—
the first non-linear channel path extends from the source toward the drain, turns and extends along the front second gate component in a first direction, and turns around the first side of the front second gate component and extends to the drain, wherein the front second gate component and the left first gate component cooperate to control a first electrical current flowing through the first non-linear channel path, and
the second non-linear channel path extends from the source toward the drain, turns and extends along the front second gate component in a second direction, and turns and around the second side of the front second gate component and extends to the drain, wherein the front second gate component and the right first gate component cooperate to control a second electrical current flowing through the second non-linear channel path.

15. The planar junction field-effect transistor of claim 14, wherein the front second gate component is spaced apart from the source by a distance that is at least sufficient to achieve a breakdown voltage between the front second gate component and the source.

16. The planar junction field-effect transistor of claim 14, wherein the front second gate component extends between two-tenths (0.2) and two (2) micrometers in a first dimension and between two-tenths (0.2) and two (2) micrometers in a second dimension.

17. The planar junction field-effect transistor of claim 14, wherein—
the volume of semiconductor material includes an N-type epitaxial semiconductor material;
the source includes an N+ material;
the drain includes an N+ substrate material; and
the first gate and the second gate include a P+ material.

18. The planar junction field-effect transistor of claim 14, further including—
a first electrical terminal provided on the source;
a second electrical terminal provided on the drain;
a third electrical terminal provided on the left first gate component;
a fourth electrical terminal provided on the right first gate component; and
a fifth electrical terminal provided on the rear second gate component.
